(19) United States
(12) Patent Application Publication
(10) Pub. No.: US 2007/0020893 A1
(43) Pub. Date: Jan. 25, 2007

(54) Low defect epitaxial semiconductor substrate having gettering function, image sensor using the same, and fabrication method thereof

(75) Inventors: Tetsuji Ueno, Suwon-si (KR); Hwa-sung Rhee, Seongnam-si (KR); Ho Lee, Cheonan-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/489,901

(22) Filed: Jul. 20, 2006

(30) Foreign Application Priority Data
Jul. 25, 2005 (KR) 10-2005-0067451

(51) Int. Cl. H01L 21/20

(52) U.S. Cl. 438/479

(57) ABSTRACT

Low defect epitaxial semiconductor substrates having a gettering function and methods of fabricating such substrates are described. A substrate in accordance with this invention includes a semiconductor substrate, a non-carrier characteristic dopant layer formed in the semiconductor substrate, a carrier characteristic dopant layer including the non-carrier characteristic dopant layer therein, and an epi-layer formed on a surface of the semiconductor substrate.

### CROSS-REFERENCE TO RELATED APPLICATION

This application is based on and claims priority from Korean Patent Application No. 10-2005-0067451 filed on Jul. 25, 2005, in the Korean Intellectual Property Office, the disclosure of which is incorporated herein in its entirety by reference.

### BACKGROUND OF THE INVENTION

1. Field of the Invention

The present invention relates, in general, to a semiconductor substrate and, more particularly, to a low defect epitaxial semiconductor substrate having a gettering function, an image sensor using the same, and a method of fabricating the same.

2. Description of the Related Art

In the manufacture of semiconductor devices, CZ substrates grown by the CZ (Czochralski) method, MCZ substrates grown by the MCZ (magnetic field Czochralski) method, and epitaxial substrates with epitaxial layers thereon are generally used. Particularly, epitaxial substrates, mainly used in image sensors, are intended to reduce uneven image contrast caused by dopant concentration heterogeneities. Typically, epitaxial substrates are formed by the method of epitaxial growth of crystalline structures on substrates using a silicon source gas such as DCS (Dichlorosilane) and TCS (Trichlorosilane). In this method, significant amounts of impurities typically become incorporated into the epitaxial layer. Particularly, metal impurities may be introduced along the growth path of an epitaxial growth apparatus or come from a source gas pipeline, both of which are typically made from SUS (stainless use steel). For instance, if chloride is contained in the source gas, hydrochloric acid (HCl) is produced during the epitaxial growth. HCl erodes SUS members, and metal chlorides may become entrained in the source gas and thus be introduced into the epi-layer. Further, epitaxial substrates may become contaminated with heavy metals, such as iron, copper, and nickel, eroded from the surfaces of manufacturing devices used in the manufacturing process.

When they are utilized in image sensors employing such contaminated epitaxial substrates, the metal impurities in the substrates cause so-called dark-currents and white defects, thereby deteriorating the properties of the semiconductor device and decreasing the production yield of the image sensors formed using such substrates.

The implantation of carbon ions into a gettering layer of a substrate has been suggested as a possible solution to the problem of metal impurities. However, an implant impact, which may occur during the carbon ion implantation step, itself causes defects and affects the heterogeneity of the substrates, thereby adding to the white defects of the image sensors formed using such substrates.

Even providing an annealing process step does not assure complete control over these substrate defects, and such an annealing step suffers from the disadvantage of requiring subjecting the substrate to high temperatures for a long period of time.

These and other problems with and limitations of the prior art techniques are addressed in whole or at least in part by the epitaxial substrates and methods for fabricating such epitaxial substrates according to this invention.

### SUMMARY OF THE INVENTION

In accordance with an aspect of the present invention, an epitaxial substrate is provided that includes a semiconductor substrate, a non-carrier characteristic dopant layer formed in the semiconductor substrate, a carrier characteristic dopant layer including the non-carrier characteristic dopant layer therein, and an epi-layer formed on a main surface of the semiconductor substrate.

In accordance with another aspect of the present invention, an image sensor formed on a low defect epitaxial substrate having a gettering function is provided.

In accordance with a further aspect of the present invention, a method is provided for fabricating an epitaxial substrate, including forming a non-carrier characteristic dopant layer and a carrier characteristic dopant layer including the non-carrier characteristic dopant layer therein in a semiconductor substrate, and for forming an epi-layer on a main surface of such a semiconductor substrate.

Other details of the present invention will be given with reference to the following description of the drawings and the preferred embodiments of the present invention as described below.

### BRIEF DESCRIPTION OF THE DRAWINGS

The above and other objects, features and advantages of the present invention will be more clearly understood from the following detailed description taken in conjunction with the accompanying drawings, in which:

FIGS. 1, 2, 6 and 7 are schematic cross-sectional views illustrating an epitaxial substrate and a method of fabricating the same in accordance with an embodiment of the present invention;

FIG. 3 is a graph illustrating how the presence of the carrier characteristic dopant layer 30 can facilitate the step of curing substrate defects caused by the ion implantation step used to form the non-carrier characteristic dopant layer 20.

FIGS. 4 and 5 are graphs illustrating two alternative ion implantation techniques.

FIG. 8 is a schematic cross-sectional view illustrating an epitaxial substrate and a method of fabricating the same in accordance with another embodiment of the present invention;

FIG. 9 is a schematic cross-sectional view illustrating an epitaxial substrate and a method of fabricating the same in accordance with a further embodiment of the present invention; and

FIG. 10 is a schematic cross-sectional view illustrating an image sensor device employing an epitaxial substrate formed according to an embodiment of the present invention and a method of fabricating the same.

### DETAILED DESCRIPTION OF THE INVENTION

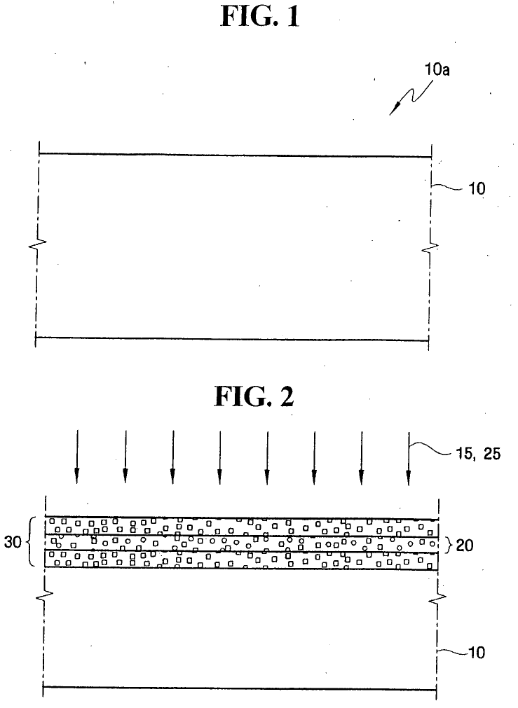

With reference to FIGS. 1 to 7, a method of fabricating an epitaxial substrate in accordance with an embodiment of the present invention is illustrated, along with the finished epitaxial substrate.

First, a semiconductor substrate 10, as shown in FIG. 1, is provided and suitably prepared for growing an epitaxial layer (epi-layer) thereon to form an epitaxial substrate. For instance, a monocrystalline silicon ingot, after being grown by a CZ method, is shaped into a wafer. The substrate 10 may be further processed if desired to provide a mirror-finished surface as a main substrate surface 10a. The semiconductor substrate 10 may preferably be about 8 inches or larger in diameter, and it preferably has a resistivity in the range of about 1 to 10 Ωcm.

The semiconductor substrate 10 may preferably be based on elements of Group 14 of the Periodic Table of Elements, exemplified by Si, Ge and SiGe substrates.

Also, the semiconductor substrate 10 may be an n-type substrate that is doped with impurities such as phosphorus (P) or arsenic (As), or alternatively a p-type substrate that is doped with impurities such as boron (B). The type of semiconductor substrate is determined depending on the particular desired properties of the image sensor device to be constructed thereon.

Next, the semiconductor substrate 10 is cleaned, for example, with an NH₄OH/H₂O₂ solution, an HF solution diluted with deionized water, and/or with others—such cleaning agents to eliminate contaminants such as particles, organic matter, and the like from the substrate. This cleaning step is also advantageous because it further reduces surface roughness. Further, use of an HCl/H₂O₂ cleaning solution cleans off traces of metal. Subsequently, baking of the substrate is performed at about 1100° C. at 20 torr in a hydrogen (H₂) atmosphere to remove oxygen from the semiconductor substrate 10.

Thereafter, a thermal oxidation process is performed to form an oxide film (not shown in FIG. 1) about 20 nm thick. The oxide film is intended to prevent or minimize channeling during a subsequent ion implantation step.

Referring now to FIG. 2, a carrier-characteristic dopant layer 30, including a non-carrier characteristic dopant layer 20 therein, is formed on the substrate 10.

The term “a carrier characteristic dopant layer 30 including a non-carrier characteristic dopant layer 20 therein” as used herein means that either both the upper and the lower surfaces of the non-carrier characteristic dopant layer 20 are included in the carrier characteristic dopant layer 30, or alternatively that only one of them is in contact with the carrier characteristic dopant layer 30. The term “a carrier characteristic dopant layer 30 encompassing a non-carrier characteristic dopant layer 20 therein” as used herein means that both the upper and the lower surfaces of the non-carrier characteristic dopant layer 20 are included or encompassed in the carrier characteristic dopant layer 30.

The term “carrier characteristic dopant” as used herein means a dopant material that is capable of generating electric information mediators, such as electrons or holes, in semiconductors; and, the term “non-carrier characteristic dopant” as used herein means a dopant material that is not capable of affecting the electric characteristics of semiconductors.

The non-carrier characteristic dopant layer 20 may be formed before the carrier characteristic dopant layer 30, or vice versa, using ion implantation techniques.

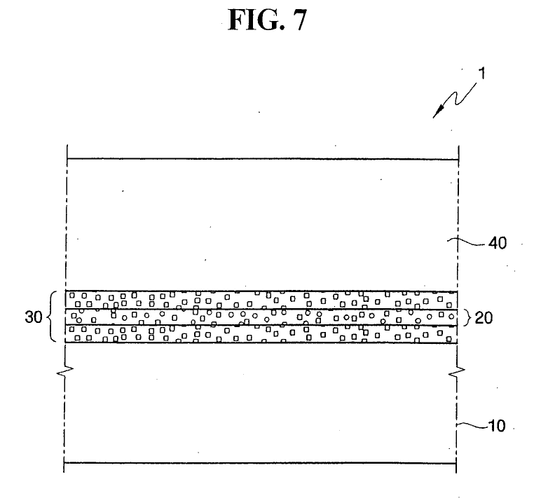

The non-carrier characteristic dopant layer 20 has been found to play a role in gettering metal impurities that might be introduced upon the subsequent formation of an epi-layer (such as indicated by reference numeral 40 in FIG. 7). That is, if a metal impurity is diffused into the substrate during a subsequent epi-layer formation process, the implanted non-carrier characteristic dopants of the non-carrier characteristic dopant layer 20 should be capable of associating with the metal impurity to form stable complexes within which the metal impurity is confined. Therefore, elements of Group 14, such as carbon (C), germanium (Ge), tin (Sn), and lead (Pb) may be used as effective non-carrier dopants in accordance with this invention for minimizing the impact of metal impurities introduced into the substrate. The ion implantation process is represented by the arrows 15 in FIG. 2.

Depending on the operational specifications of the ion implanter employed, the acceleration energy for the ion implantation step usually ranges from 70 to 150 KeV, which makes the projection range (hereinafter referred to “Rp”) set at a position 0.25 to 0.50 μm away from the surface of the substrate.

Generally, a thicker gettering layer shows a higher gettering efficiency. Also, the capacity for gettering metal impurities improves as the dopant ions are implanted at a higher peak doping concentration. However, a balance must be achieved because high peak doping concentrations may increase defects, resulting in degrading the crystallinity of the substrate 10 and thus the crystallinity of the epi-layer 40 to be grown on the substrate 10.

Accordingly, the non-carrier dopant layer 20 is preferably formed to a thickness of about 0.05 μm or more, sufficiently for gettering metal impurities, and more preferably in a thickness ranging from about 0.5 to 2 μm. In order to guarantee this thickness, for instance, carbon dopants are implanted at a dose ranging from about 5×10¹³ to 5×10¹⁵/cm², and preferably at a dose of about 5×10¹⁴/cm², in consideration of a subsequent annealing process.

Herein, the term “thickness” means the range space of an ion implantation profile in which the concentration of impurities is higher than about 10⁻¹⁸/cm².

The carrier characteristic dopant layer 30 is formed to improve the regrowth that occurs upon performing an annealing process on the substrate for curing the defects attributed to the ion implantation step previously used for the formation of the non-carrier characteristic dopant layer 20.

Hence, the carrier characteristic dopant layer 30 may be formed through the ion implantation of elements of Groups 13 or 15 of the Periodic Table of Elements. For instance, boron (B) or arsenic (As), representative of elements of Groups 13 or 15, may be used in this step of the method.

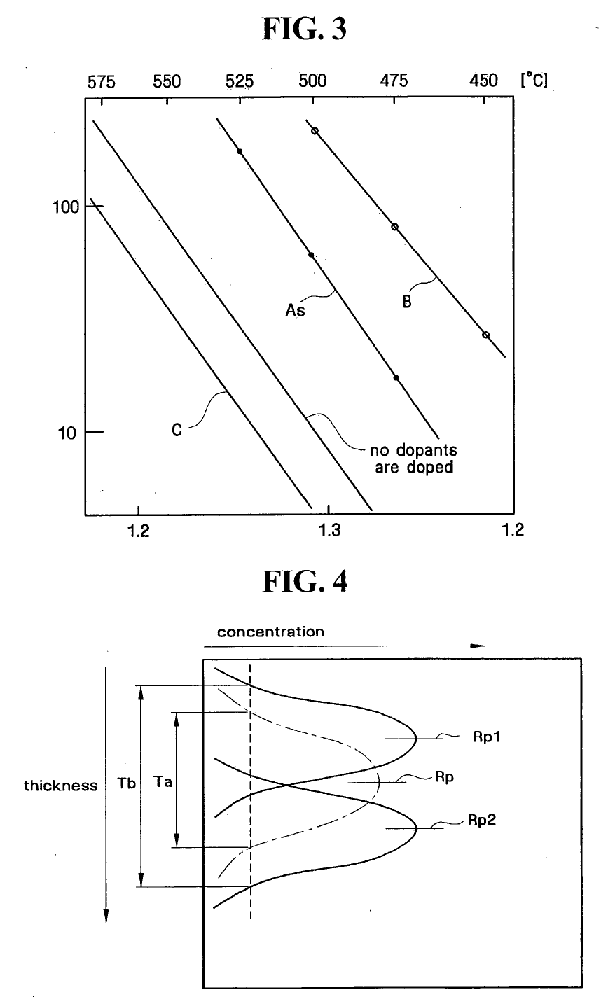

Turning to FIG. 3, a graph is provided to help in describing the function of the carrier characteristic dopant layer 30. As seen in this graph, the regrowth step is successfully performed at lower temperatures and at higher rates of speed when a carrier characteristic dopant such as arsenic or boron is used than when no dopants are doped or when the non-carrier characteristic dopant carbon is used. For example, as seen in FIG. 3, the regrowth rate is about 20 times faster when boron is doped as part of the non-carrier characteristic dopant layer than when carbon is doped. This indicates that the regrowth step with boron can be finished in only one twentieth of the time that is needed with carbon as the dopant at the same temperature.

If carrier characteristic dopants are present in the substrate 10, the carrier density in the Fermi level of the substrate 10 increases, which decreases the activation energy. Therefore, the regrowth step can be accomplished within a short period of time at relatively low temperatures. On the other hand, when the non-carrier characteristic dopant carbon is implanted, not only is the carrier density of the substrate 10 in the Fermi level low, but also carbon atoms, different in size from Si, are interposed in a Si lattice to cause atomic level strain, thereby requiring higher activation energies. Accordingly, under these conditions, the regrowth is accomplished only slowly and at relatively high temperatures.

In other words, the presence of the carrier-characteristic dopant layer 30 within the substrate 10 makes it easier to conduct an annealing process for curing the defects that might occur upon the formation of the non-carrier characteristic dopant layer 20.

Hence, when the carrier characteristic dopant layer 30 completely covers and encompasses both the upper and the lower surfaces of the non-carrier dopant layer 20, it is possible to cure any such defects in the device more effectively. When the carrier characteristic dopant layer 30 is thick enough to completely include the non-carrier characteristic dopant layer 20 therein, substantially all of the defects occurring during the formation of the non-carrier characteristic dopant layer 20 can be cured.

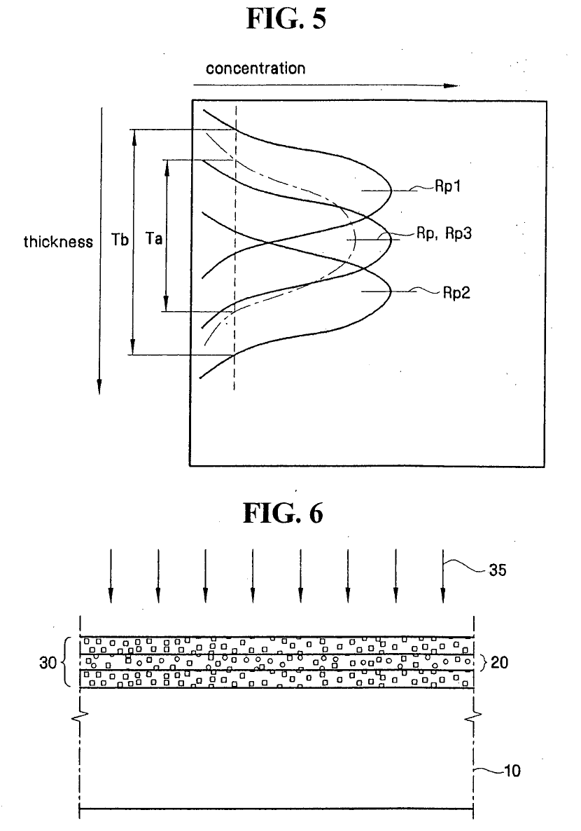

In order that the non-carrier characteristic dopant layer 20 be encompassed within the carrier characteristic dopant layer 30, carrier characteristic dopants, as shown in FIGS. 4 and 5, may be implanted at least twice, each at a different Rp to form the carrier characteristic dopant layer 30.

For instance, as shown in FIG. 4, ion implantation is performed twice in a partitioned manner at a fit Rp (Rp₁) and a second Rp (Rp₂), respectively smaller and larger than the Rp (Rp) used for the ion implantation of the non-carrier characteristic dopant layer 20. Alternatively, multi-ion implantation may be conducted, as shown in FIG. 5, with a first small Rp (Rp₁), a second large Rp (Rp₂) and a third mid-range Rp (Rp₃) that is substantially identical to the Rp (Rp) used for the ion implantation of the non-carrier dopant layer 20.

When such an implantation process is conducted, as shown in FIGS. 4 and 5, the carrier characteristic dopant layer 30 has a thickness (Tb) larger than that (Ta) of the non-carrier dopant layer 20. As used herein, the term “thickness” means the range space of an ion implantation profile in which the concentration of impurities is higher than about 10⁻¹⁸/cm².

As such, the multi-ion implantation technique described above allows the co-existence of both non-carrier characteristic dopants (e.g., carbon) and carrier-characteristic dopants (e.g., boron) in the non-carrier characteristic dopant layer 20, as shown in FIGS. 4 and 5.

With reference to FIG. 6, an annealing process may then be performed on the device with heat applied in the direction indicated by the arrows 35.

Preferred conditions for this annealing process 35 include a temperature range of from about 900 to 1,000° C. and a nitrogen atmosphere. This annealing process 35 functions to recrystallize a substrate surface 10a (see FIG. 1) which may have been made at least partially amorphous by the ion implantation step.

As described above, the carrier density is increased near the Fermi level of the substrate 10 by the carrier characteristic dopant layer 30, so that the recrystallization can be readily accomplished by this annealing step. Thus, even if the annealing process is conducted for as little as 10 min. or less, for example, for about 1 to 3 min., a sufficient level of regrowth can be achieved to restore satisfactory performance characteristics. Particularly, the substrate 10 comprising the non-carrier dopant layer 20, and the mirror-finished surface 10a, which may have been made at least partially amorphous by the ion implantation step, can be effectively regrown.

With reference to FIG. 7, an epi-layer 40 is formed on a main surface of the substrate 10 on which substantially complete regrowth has taken place using an annealing step as described above.

Using an etchant including HF, the oxide film (not shown) that was earlier formed on the main surface of the substrate 10 is now removed, followed by the step of growing the epi-layer 40 by the simultaneous supply of a silicon source gas and a dopant source gas to the surface of the substrate.

An n-type or a p-type epi-layer may be formed on an n-type substrate, or vice versa.

As one example, in order to effectively prevent crosstalk of the image sensor and to omit a p-type well for separating photoelectric conversion devices from each other, a p-type epi-layer (indicated by reference numeral 40 of FIG. 7) may be formed on an n-type substrate 10.

In this regard, a useful silicon source gas may be selected from the group consisting of SiH₂Cl₂, SiHCl₃, SiCl₄, SiH₄, Si₂H₆ and combinations thereof, while PH₃ and B₂H₆ may be used as the respective dopant source gases for forming an n-type epi-layer or a p-type epi-layer, respectively.

The formation of the epi-layer 40 may be performed at a temperature ranging from about 1000 to 1100° C. under a pressure ranging from about 10 to 760 Torr. The epi-layer 40 thus formed may range in resistance from about 20 to 150 Ω so as to increase the sensitivity of the resulting photo diode and to reduce the crosstalk thereof.

The thickness of the epi-layer 40 is determined depending on the desired properties of the image sensor to be formed thereon. Thus, the epi-layer thickness may be about 1 μm or greater; for example, it may range from about 2 to 5 μm thick, but is not limited to that thickness range. However, the epi-layer 40 must be thick enough to form a photodiode therein.

As shown in FIG. 7, the epitaxial substrate 1 fabricated in accordance with a first embodiment of the present invention comprises a semiconductor substrate 10, a non-carrier characteristic dopant layer 20, a carrier characteristic dopant layer 30, which includes or encompasses the non-carrier characteristic dopant layer 20 therein, and an epi-layer 40. The carrier characteristic dopant layer 30 functions to facilitate recrystallizing the substrate 10, which may be made at least partially amorphous by the ion implantation step for the formation of the non-carrier characteristic dopant layer 20.

Because each individual layer of the substrate 1 in FIG. 7 has already been described above with regard to its function, constituting material(s), resistance characteristics, and layer thickness, a further description thereof is omitted.

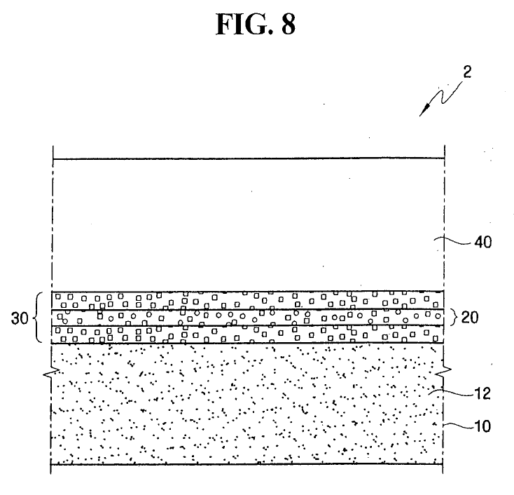

Referring to FIG. 8, a schematic cross-sectional view is provided for illustrating the structure of an epitaxial substrate 2 and a fabrication method thereof in accordance with another embodiment of the present invention.

Unlike substrate 1 of FIG. 7, the epitaxial substrate 2 of FIG. 8 has an oxygen precipitate formed in the semiconductor substrate 10, which is capable of gettering metal impurities. Generally, a semiconductor substrate 10 grown by a CZ method already contains some interstitial oxygen as an impurity. Thermal treatment makes this oxygen impurity oversaturated so as to form oxygen eductions 12 as heterogeneous regions dispersed through the substrate 10. A gettering function performed utilizing such oxygen eductions may be called internal gettering (IG).

The oxygen eductions shown in FIG. 8 can be formed in various manners. First, after epitaxial growth, the epitaxial substrate 2 may be thermally treated at a predetermined temperature, for example, at a temperature of about 450 to 750° C., for at least 30 min. Alternatively, the epitaxial substrate 2 may be heated to a temperature of from about 800 to 1,000° C. at an elevation rate of about 3° C./min. and then treated at about 1,000° C. for about 4 hours; In alternative embodiments, before the thermal treatment, certain elements such as H₂, He, B, C, O₂, Ge, Sb or combinations thereof, may be implanted into the epitaxial substrate 2 in order to improve the eduction rate of oxygen.

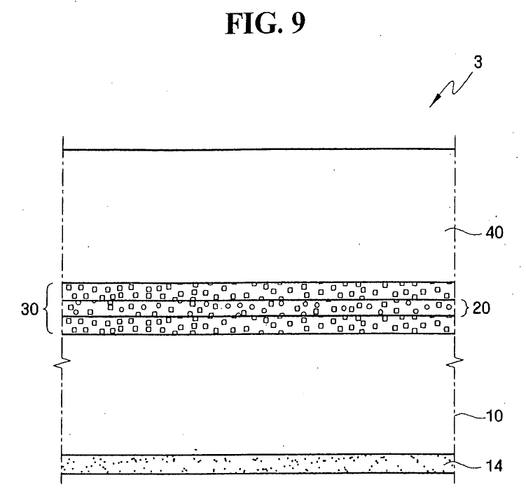

With reference to FIG. 9, an epitaxial substrate 3 is shown in accordance with a further embodiment of the present invention.

Unlike substrate 10 of FIG. 1 or substrate 1 of FIG. 7, the epitaxial substrate 3 of FIG. 9 has an extrinsic gettering layer 14 formed on the backside thereof Herein, the extrinsic gettering layer 14 may be a polysilicon layer effective for gettering iron, copper, and other such impurities, or it may be a layer of substrate that has been mechanically distorted, such as by means of a sand blast, and thereby functions as a getting layer 14. A gettering function performed utilizing such an extrinsic gettering layer may be called extrinsic gettering (EG).

For example, the polysilicon layer on the backside of the epitaxial substrate may be obtained by forming a polysilicon layer over the entire surface of the substrate 10 as seen in FIG. 1 and then removing the polysilicon layer formed on the mirror-finished surface 10a by grinding. Alternatively, SiH₄ may be applied only on the backside of the substrate 10 to form a polysilicon layer thereon. It is preferred in this invention embodiment that the polysilicon layer be formed before the growth of the epi-layer 40.

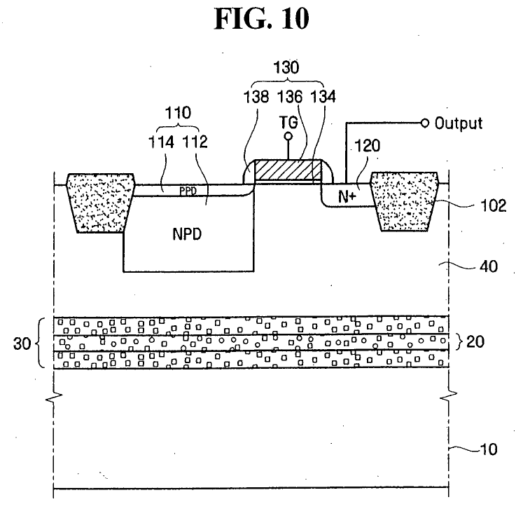

FIG. 10 schematically shows an image sensor device utilizing a substrate according to an embodiment of the present invention and illustrates a method of fabricating the same.

Although a CMOS-type image sensor is shown in FIG. 10, an image sensor according to the present invention is not limited thereto, and may be formed by applying either or both of an NMOS and a PMOS process.

First, an epitaxial substrate, such as substrate 1 in FIG. 7, prepared according to an embodiment of the present invention is provided. Subsequently, an image sensor is formed on the epitaxial substrate 1. The image sensor may have various structures depending on the intended use of the completed device. For instance, 3 to 5 transistor structures may be formed on the epitaxial substrate. Also, the fabrication of the image sensor may be modified in various ways depending on the desired structure and design.

In FIG. 10, the image sensor is structured to have one pinned photo diode (PPD) as a photoelectric conversion device, together with four transistors.

Referring to FIG. 10, the image sensor according to an embodiment of the present invention includes a substrate 1, as seen in FIG. 7, an element isolation region 102, a photoelectric conversion device 110, a floating diffusion region 120, and a charge transfer logic 130. In the epitaxial substrate 1, at least an active region and an element isolation region are formed, with the photoelectric conversion device 110 and the charge transfer logic 130 formed therewithin.

The epitaxial substrate 1 according to an embodiment of the present invention includes an in-situ carbon-doped gettering layer 30 capable of gettering metal impurities.

The element isolation region 102 is formed to define an active region on the epitaxial substrate 1, for example using a shallow trench isolation (STI) process.

Functioning to absorb light energy and accumulate generated charges, the photoelectric conversion device 110 consists of an N⁺-type photodiode 112 and a P⁺-type pinning layer 114. Typically, the photodiode 112 and the pinning layer 114 are formed through two different ion implantation processes. Then in neighboring sources and drains, for example, N⁺ dopants are implanted more deeply to form a photodiode 112. Using a low energy, P⁺ dopants are implanted at a high dose to form a pinning layer 114 over the photodiode 112. Of course, the doping position and dose depend on the specific fabrication process and design.

The floating diffusion region 120, typically formed by the ion implantation of N⁺ dopants, receives the charges from the photoelectric conversion device 110 through the charge transfer logic 130. Located on a channel between the photoelectric conversion device 110 and the floating diffusion region 120, the charge transfer logic 130 includes a gate dielectric film 134, a gate 136, and spacers formed on side walls of the gate 136.

The charge transfer device 130 may employ an enhancement type transistor or a depletion type transistor in order to prevent the photoelectric conversion device 110 from undergoing an overflow or blooming phenomenon that might otherwise occur upon exposure to excessive light energy.

The carrier characteristic dopant layer 30, including or encompassing the non-carrier characteristic dopant layer 20, greatly reduces defects of the epitaxial substrate 1, allowing for the formation of good quality image sensors.

Metal impurities generated during the fabrication of the epitaxial substrate 1 and/or the image sensor create a midgap level or trap level between a valance band and a conduction band. Thus, charges are readily produced even with low thermal energy through R-G center generation. Thus, even if the material is not exposed, the charge transfer logic 130 can produce charges which then migrate through the channel under charge transfer logic 130 even when the charge transfer logic 130 remains inactive, thereby generating so-called dark-currents. In addition, excessive, heterogeneous dark-currents are the cause of the so-called white defect responsible for a signal output larger than normal. Further, an image sensor having metal impurities has a relatively small dynamic range because it cannot definitely discriminate between brightness and darkness. In contrast, the image sensor according to an embodiment of the present invention can greatly reduce such common defects, such as dark-currents, white defects, and so on, because the non-carrier characteristic dopant layer 20 is capable of efficiently gettering the metal impurities.

It should be understood that although the image sensor shown in FIG. 10 employs the epitaxial substrate 1 illustrated in FIG. 7, the epitaxial substrates of FIGS. 8 and 9, or other epitaxial substrates according to this invention, could be applied for the fabrication of an image sensor according to this invention.

It should also be apparent to those skilled in the art that an epitaxial substrate according to the present invention can be advantageously applied to devices other than an image sensor. As expected, such devices based on an epitaxial substrate of the present invention enjoy the various advantages described above, such as substantially fault-free operation and a long life span, because the substrate is only minimally contaminated with metal impurities.

As previously described, an epitaxial substrate and methods of fabricating the same in accordance with the present invention produces the following desirable effects.

First, the presence of the non-carrier characteristic dopant layer allows the gettering of metal impurities.

Second, the carrier characteristic dopant layer, including the non-carrier characteristic layer therein, can readily cure defects of such epitaxial substrates.

Finally, an annealing process for curing defects of substrates can be performed in a relatively short period of time due to the presence of the carrier characteristic dopant layer.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. An epitaxial substrate comprising:
a semiconductor substrate;
a non-carrier characteristic dopant layer formed in the semiconductor substrate;
a carrier characteristic dopant layer including the non-carrier characteristic dopant layer therein; and
an epi-layer formed on a surface of the semiconductor substrate.

2. The epitaxial substrate of claim 1, wherein the non-carrier characteristic dopant layer is formed using a dopant selected from the group consisting of carbon, germanium, tin, lead and combinations thereof.

3. The epitaxial substrate of claim 1, wherein the carrier characteristic dopant layer is formed using a dopant selected from the group consisting of elements of Group 13 and Group 15 of the Periodic Table of Elements.

4. The epitaxial substrate of claim 1, wherein the non-carrier characteristic dopant layer is formed using carbon and the carrier characteristic dopant layer is formed using boron.

5. The epitaxial substrate of claim 4, wherein the semiconductor substrate is n-type and the epi-layer is p-type.

6. The epitaxial substrate of claim 1, wherein the semiconductor substrate is n-type and the epi-layer is p-type.

7. The epitaxial substrate of claim 1, wherein the non-carrier characteristic dopant layer ranges has a thickness in the range of about 0.5 to 2 μm.

8. The epitaxial substrate of claim 1, wherein the non-carrier characteristic dopant layer ranges in peak doping concentration from about 1×10¹⁹ to 5×10²⁰/cm².

9. The epitaxial substrate of claim 1, wherein the non-carrier characteristic dopant layer has both carrier characteristic dopants and non-carrier characteristic dopants.

10. The epitaxial substrate of claim 1, wherein either: (a) the carrier characteristic dopant layer is formed by implanting carrier characteristic dopants twice at different first and second respective projection ranges, while the non-carrier characteristic dopant layer is formed by implanting non-carrier characteristic dopants at a third projection range that is intermediate between the first and second projection ranges; or, (b) the carrier characteristic dopant layer is formed by implanting carrier characteristic dopants three times at different first, second and third respective projection ranges, while the non-carrier characteristic dopant layer is formed by implanting non-carrier characteristic dopants at a fourth projection range substantially defined by a middle range of the first, second and third projection ranges.

11. The epitaxial substrate of claim 1, further comprising an extrinsic gettering layer on a backside of the semiconductor substrate.

12. The epitaxial substrate of claim 1, wherein the semiconductor substrate has oxygen eductions located below the carrier characteristic dopant layer, said oxygen eductions being capable of gettering metal impurities.

13. An image sensor formed on an epitaxial substrate according to any one of claims 1 to 12.

14. A method of fabricating an epitaxial substrate, comprising the steps of:
forming a non-carrier characteristic dopant layer and a carrier characteristic dopant layer including the non-carrier characteristic dopant layer therein in a semiconductor substrate; and
forming an epi-layer on a surface of the semiconductor substrate.

15. The method of claim 14, further comprising the step of annealing the semiconductor substrate before forming the epi-layer.

16. The method of claim 15, wherein the annealing step is performed at a temperature of about 900 to about 1,000° C. for about 1 to 3 min.

17. The method of claim 14, wherein the non-carrier characteristic dopant layer is formed using a dopant selected from the group consisting of carbon, germanium, tin, lead, and combinations thereof.

18. The method of claim 14, wherein the carrier characteristic dopant layer is formed using a dopant selected from the group consisting of elements of Group 13 and Group 15 of the Periodic Table of Elements.

19. The method of claim 14, wherein the non-carrier characteristic dopant layer is formed using carbon and the carrier characteristic dopant layer is formed using boron.

20. The method of claim 19, wherein the semiconductor substrate is n-type and the epi-layer formed thereon is p-type.

21. The method of claim 14, wherein the semiconductor substrate is n-type and the epi-layer formed thereon is p-type.

22. The method of claim 14, wherein the non-carrier characteristic dopant layer has a thickness in the range of about 0.5 to 2 μm.

23. The method of claim 14, wherein the non-carrier characteristic dopant layer has a peak doping concentration in the range from about 1×10¹⁹ to 5×10²⁰/cm².

24. The method of claim 14, wherein either: (a) the carrier characteristic dopant layer is formed by implanting carrier characteristic dopants twice at different first and second respective projection ranges, while the non-carrier characteristic dopant layer is formed by implanting non-carrier characteristic dopants at a third projection range that is intermediate between the first and second projection ranges; or, (b) the carrier characteristic dopant layer is formed by implanting carrier characteristic dopants three times at different fist, second and third respective projection ranges while the non-carrier characteristic dopant layer is formed by implanting non-carrier characteristic dopants at a fourth projection range substantially defined by the middle range of the first, second and third projection ranges.

25. The method of claim 14, further comprising forming an extrinsic gettering layer on a backside of the semiconductor substrate before forming the epi-layer.

26. The method of claim 14, wherein the semiconductor substrate has oxygen eductions located below the carrier characteristic dopant layer, said oxygen eductions being capable of gettering metal impurities below the carrier characteristic dopant layer, said oxygen eductions being formed by the step of annealing the semiconductor substrate after forming the epi-layer.
